(19) United States
(12) Patent Application Publication
(10) Pub. No.: US 2004/0128603 A1
(43) Pub. Date: Jul. 1, 2004

(54) Device for testing the conformity of an electronic connection

(76) Inventor: Jacques Reberga, Saint-Loup-De-Fribois (FR)

Correspondence Address: Corporate Patent Counsel, Philips Electronics North America Corporation, P O Box 3001, Briarcliff Manor, NY, 10510, US

(21) Appl. No.: 10/477,488

(22) PCT Filed: May 15, 2002
(86) PCT No.: PCT/IB02/01695

(30) Foreign Application Priority Data
May 15, 2001 (FR) 01/06394

(51) Int. Cl. G06F 11/00; G01R 31/28

(52) U.S. Cl. 714/738

(57) ABSTRACT

A device for testing the conformity of an electronic connection (1), the device comprising a first signal generator (3) supplying a sequence of input bits to a first extremity (E) of the connection (1), and an error detection device (6) receiving a sequence of output bits from a second extremity (S) of the connection (1), in response to the sequence of input bits. The error detection device (6) comprises:

a second signal generator (10) intended to recreate the sequence of input bits and being suitable for predicting the value of the next bit when the second extremity (S) supplies a bit of the output sequence, and

information means (14) indicating the presence of an error with means (13) for comparing the value of the predicted bit with the effective value of the next bit of the sequence of output bits.

Application: notably for testing integrated circuits.

### FIELD OF THE INVENTION

The invention relates to test devices intended to verify the conformity of an electronic connection between two devices, for example, between two integrated circuits or between an input and an output of one and the same integrated circuit. The invention is particularly, but not exclusively applicable for testing integrated circuits for switching data at a high rate in order to verify whether the data to be sent through the circuit are not altered during their transmission. The rates concerned may range, for example, up to 3.2 gigabits per second. It is also applicable to testing memories and, more generally any device to which an input signal is applied and from which an output signal which must correspond to the input signal is obtained.

### BACKGROUND OF THE INVENTION

To effect such tests, it is necessary to have a signal generator applying a sequence of input bits to one of the extremities of the connection. A sequence of output bits is recovered from the other extremity of the connection and the two bit sequences are compared, and an error is identified when the two bit sequences are different. In order that the comparison is useful, it is necessary that the two sequences to be compared should be in perfect synchronism with each other. It is necessary to know the propagation time of the sequence of input bits between the two extremities of the connection and to have a device for consequently delaying the sequence of input bits at the input of the comparator. The precise knowledge of this propagation time is very difficult to gain, notably in the case of high rate transmissions.

As described in U.S. Pat. No. 6,118,294, it is possible to provide a memory with which the sequence of input bits can be stored, which is this stored test sequence which is compared with the test sequence at the output. Such a circuit allows simplification of the afore mentioned synchronizing problems. However, such a procedure will be extremely difficult if the circuits must be tested with long bit sequences because the memory capacities to be used must be very large. Moreover, it is necessary to know, in advance, the sequence of input bits so as to store it in the memory before the test can be started, and this excludes the use of pseudo-random sequences with which a better test quality can be obtained. Nevertheless, a synchronization is necessary between the sequence of output bits and the sequence of stored bits so as to be able to perform the comparison, but it is less difficult to obtain.

### OBJECT AND SUMMARY OF THE INVENTION

The invention provides a device for testing the conformity of an electronic connection and avoids memory usage, while eliminating problems of synchronization between the sequence of input bits and the sequence of output bits because there is no comparison between the sequence of input bits and the sequence of output bits.

To this end, the invention relates to a device for testing the conformity of an electronic connection, the device comprising a first signal generator supplying a sequence of input bits to a first extremity of the connection, and an error detection device receiving a sequence of output bits from a second extremity of the connection, in response to the sequence of input bits, characterized in that the error detection device comprises:

a second signal generator, similar to the first generator, this second signal generator being intended to recreate the sequence of input bits and being suitable for predicting the value of the next bit when the second extremity supplies a bit of the output sequence, and

information means indicating the presence of an error with means for comparing the value of the predicted bit with the effective value of the next bit of the sequence of output bits.

A clock signal at the same frequency controls the first signal generator and the second signal generator.

The first signal generator may comprise a first shift register loaded with an initial combination of the bits, associated with a first exclusive-OR gate connected, at the input, to the last stage and to the stage before the last stage of the first shift register, and, at the output, to the first stage of the first shift register.

The combination of initial bits may be supplied by fixed or programmable initialization means.

The second signal generator may comprise a second shift register, associated with a second exclusive-OR gate connected, at the input, to the last stage and to the stage before the last stage of the second shift register, and whose output supplies the bit with the predicted value.

In a first configuration, the output of the second exclusive-OR gate may be connected to the first stage of the second shift register, the second shift register being loaded with the same initial combination of bits as the first shift register.

The start of operation of the second shift register is synchronized with the start of the sequence of output bits.

In another configuration, the first stage of the second shift register may receive the sequence of output bits.

The comparison means may comprise a third exclusive-OR gate, one input of which is connected to the second signal generator and the other input receives the sequence of output bits.

The information means indicating the presence of an error may also comprise a device for validating errors, intended to mask errors which might be detected when the second signal generator is not in an operational state.

The validation device may comprise an AND gate, one input of which is connected to the output of the comparison means, and the other input is connected to a delay device which brings about a delay which is compatible with the operational state of the second signal generator.

In order that the test can continue even if an error has been detected, it is possible to provide an error correction device intended to correct an error of the sequence of output bits before its input into the second stage of the second shift register.

The correction device may comprise a fourth exclusive-OR gate, one input of which receives the sequence of output bits and the other input is connected to the output of the information means indicating the presence of an error, and whose output is connected to the first stage of the second shift register.

It may be interesting to provide means for counting detected errors, arranged at the output of the information means indicating the presence of an error.

The counting means can supply a signal when a predetermined number of errors has occurred.

The counting means may comprise a programmable counter, whose input receives the information indicating the presence of an error and whose output is connected to the input of a D-flipflop which supplies the signal.

To improve the reliability of the test device, it may be provided with a self-test device.

For the same purpose, it may be provided with means for synchronizing the sequence of output bits with the clock signal.

The means for synchronizing the sequence of output bits with the clock signal may be realized by a D-flip-flop.

Means for inverting the clock signal so as to facilitate the synchronization may be provided.

### BRIEF DESCRIPTION OF THE DRAWINGS

The invention will be better understood by reading the description of embodiments given by way of non-limitative example with reference to the accompanying drawings in which:

FIG. 1 is an embodiment of a test device according to the invention;

FIG. 2 is an embodiment of the first signal generator of the test device according to the invention;

FIGS. 3A to 3D show some examples of the error detection device of the test device according to the invention.

### DESCRIPTION OF PREFERRED EMBODIMENTS

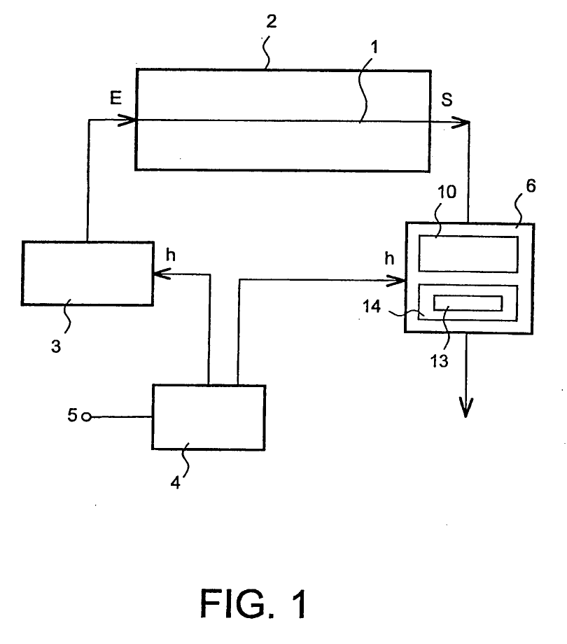

FIG. 1 shows diagrammatically a test device according to the invention.

The electronic connection to be tested is denoted by the reference numeral 1 and it is supposed that one of its extremities corresponds to an input E of an integrated circuit 2 for switching data, and the other extremity corresponds to an output S of the integrated circuit 2. The electronic connection may connect two integrated circuits.

The test device comprises a first signal generator 3 which is intended to supply a sequence of input bits to the extremity E of the connection 1. An error detection device 6 is connected to the other extremity S of the connection 1. An oscillator 4 supplies a clock signal h to the first signal generator 3. The frequency of this oscillator 4 may be voltage or current controlled by way of the terminal denoted by reference numeral 5. The oscillator 4 supplies the same clock signal h or a clock signal having the same frequency to the error detection device 6. The phase of the clock signal h is not important at the level of the first signal generator 3 and the error detection device 6. What counts is that they are controlled at the same frequency.

The error detection device 6, which will hereinafter be described in detail, receives a sequence of output bits appearing at the other extremity S of the connection 1 in response to the sequence of input bits applied to its extremity E.

In contrast to conventional test devices, the error detection device 6 according to the invention does not receive the sequence of input bits.

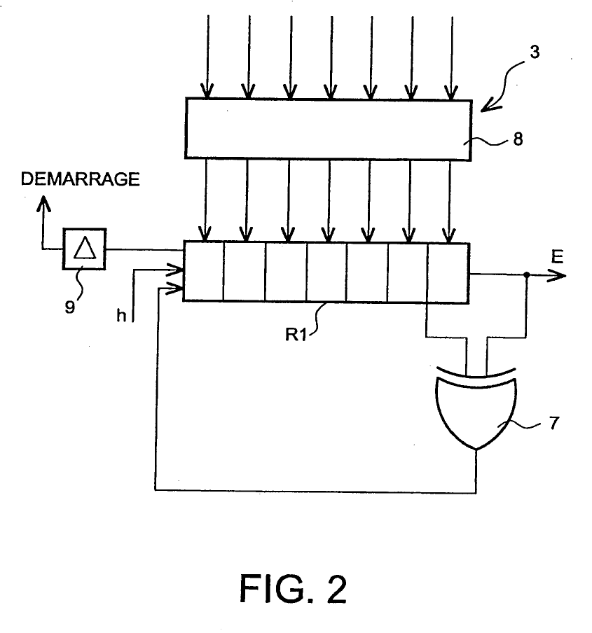

FIG. 2 shows an embodiment of the first signal generator 3. It comprises a first shift register R1, with seven stages in this embodiment. The number of stages, which may be higher than or equal to three, is given by way of non-limitative example. The first shift register R1 is controlled by the clock signal h. The first shift register R1 co-operates with a first exclusive-OR gate 7. It is connected, at the input, to the last stage and to the stage before the last stage of the first shift register R1. The first stage of a shift register corresponds to its input and the last stage corresponds to its output. The output of the first exclusive-OR gate 7 is connected to the first stage of the first shift register R1.

The first exclusive-OR gate 7 thus receives the bit at the output of the first shift register R1 and the next bit, i.e. the bit which is outputted from the first shift register R1 upon the next clock pulse.

The output of the first shift register R1, which corresponds to the output of the first signal generator 3, is connected to the extremity E of the electronic connection 1 to be tested. In operation, the first shift register R1 associated with the first exclusive-OR gate 7 supplies the sequence of input bits and, in this embodiment, this sequence is a pseudo-random sequence of 7² bits. Such a bit sequence allows finer testing of the quality of the transmission between the extremity E and the extremity S of the electronic connection 1 than a sequence which is known in advance.

An initial combination of 7 bits can be loaded into the first shift register R1 by initialization means 8. The initial combination can be fixedly or adjustably programmed.

The start of operation of the first shift register R1 takes the loading time of the initial combination into account and to this end, a delay device 9 brings about a delay Δ between the instant of starting the test and the instant of starting the operation of the first shift register R1 according to when its loading is terminated.

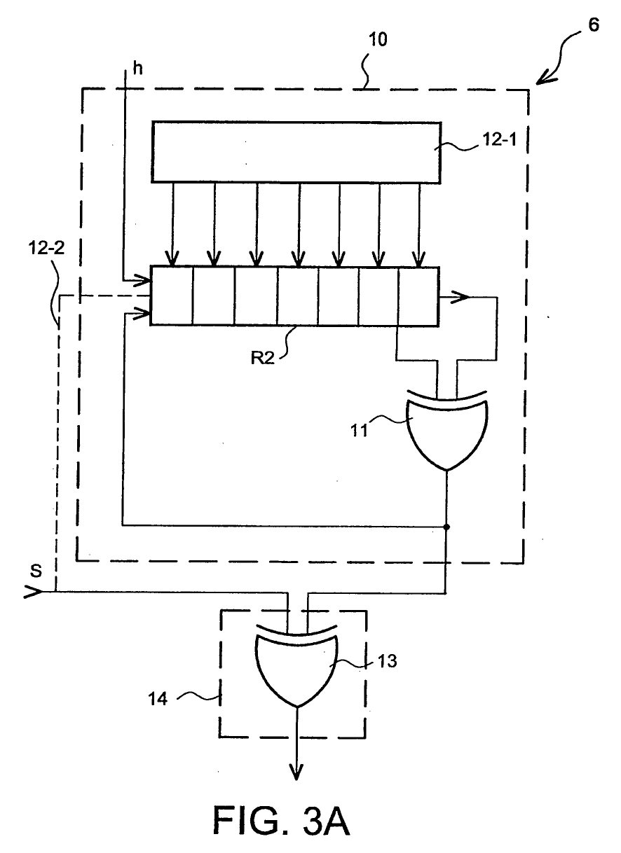

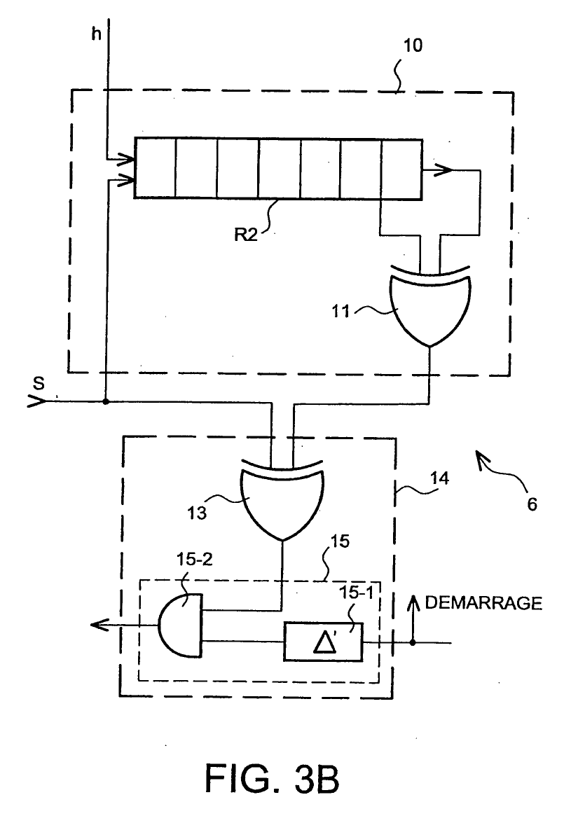

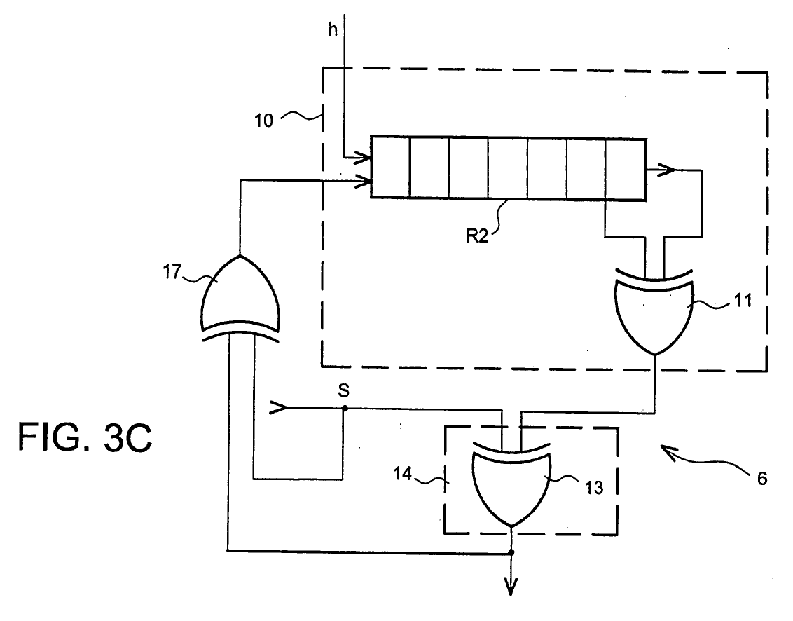

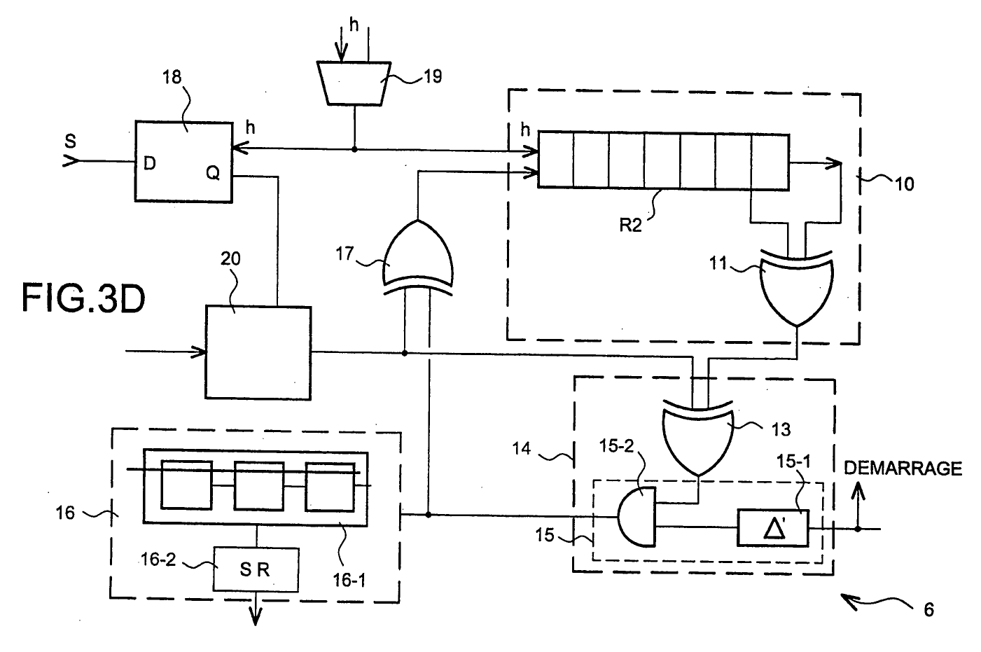

Several variants of the error detection device 6 will now be described with reference to FIG. 3A.

The error detection device 6 comprises a second signal generator 10 which is similar to the first signal generator 3. This second signal generator is intended to recreate the sequence of input bits.

In FIG. 3A, the second signal generator 10 comprises a second shift register R2 which co-operates with a second exclusive-OR gate 11. The second shift register R2 is controlled by the clock signal h from the oscillator 4. The arrangement of the second shift register R2 and the second exclusive-OR gate 11 is similar to that illustrated in FIG. 2. The second exclusive-OR gate 11 is connected at the input to the last stage and to the stage before the last stage of the second shift register R2. Its input receives the bit at the output of the second shift register R2 and the next bit, i.e. the bit coming from the second shift register R2 at the next clock pulse. The output of the second exclusive-OR gate 7 is connected to the input of the second shift register R2. In this embodiment, the second shift register R2 is loaded at the start with the same initial combination as the first shift register R1. Initialization means 12-1 allow loading of said initial combination into the second shift register R2, and synchronizing means 12-2, symbolized by the broken lines, allow starting the operation of the second shift register R2 in synchronism with the arrival of the sequence of output bits.

The same sequence of pseudo-random bits as that supplied by the first signal generator 3 is obtained at the output of the second shift register R2.

The second signal generator 10 is capable of predicting the value of the next bit when the second extremity S of the electronic connection 1 supplies a bit. The prediction of the next bit is given by the output of the second exclusive-OR gate 11.

The error detection device 6 also comprises information means 14 indicating the presence of an error, comprising means 13 for comparing the value of the predicted bit with that effectively assumed by the next bit. These comparison means 13 may comprise a third exclusive-OR gate 13, one input of which is connected to the output of the second exclusive-OR gate 11 of the second signal generator 10, and the other output is connected to the second extremity S of the electronic connection 1 to be tested.

An error is detected at the level of the electronic connection 1 when the two compared bits have different values, the output of the third exclusive-OR gate 13 supplying a bit having the value 1.

The two signal generators 3, 10 receive the same clock signal h and they have no other connection. Such a test device does not require synchronizing means nor clock signals controlling the signal generators 3, 10, nor the instant of starting operation of the two signal generators.

Instead of connecting the input of the second shift register R2 to the output of the second exclusive-OR gate 11, it is possible to connect the input of the second shift register R2 to the second extremity S of the electronic connection 1 to be tested. This configuration, illustrated in FIG. 3B, is equivalent to that in FIG. 3A because, in the absence of an error, the sequence of output bits taken from the second extremity S of the connection 1 is identical to the sequence of input bits applied to the first extremity E and coming from the first signal generator 3.

The initialization and synchronizing means are no longer necessary for loading and starting the second shift register R2. It is the sequence of output bits which progressively loads the different stages of the second shift register R2. It is sufficient to wait for the complete loading of the second shift register R2 before the result of the test can be significant.

It is preferable that the information means 14 indicating the presence of an error comprise a device 15 for validating errors intended to mask the errors detected when the second signal generator 10 is not in an operational state, i.e. at least when the second shift register R2 is not completely loaded. This is illustrated in FIG. 3B. This validation device 15 at the output of the comparison means 13 comprises a delay device 15-1 associated with an AND gate 15-2. The delay device 15-1 introduces a delay Δ′ from the instant of starting the test, compatible with the operational state of the second signal generator 10. This delay Δ′ is at least equal to the time of loading the second shift register R2, augmented by the time estimated for the propagation of the sequence of input bits through the electronic connection 1 to be tested. It will be interesting to choose a delay Δ′ which is sufficiently long so as to ensure that the test device is correctly initialized. For example, in the case of a second shift register R2 having seven stages, thus requiring seven clock pulses to be loaded completely, while the estimated propagation time of the sequence of input bits is approximately one or two clock pulses, a delay Δ′ of approximately sixteen clock pulses may be chosen, but about ten clock pulses will also be sufficient.

The output of the delay device 15-1 is connected to an input of the AND gate 15-2, which input takes the value 0 when the time is not run out and proceeds to the value 1 after this. Once the time Δ′ is run out, the validation device 15 is transparent to the errors detected by means of the comparison. The other input of the AND gate 15-2 is connected to the output of the third exclusive-OR gate 13 constituting the comparison means. The output of the AND gate 15-2 constitutes the output of the information means 14 for indicating the presence of an error. There is an error when said output assumes the value 1.

It is possible to continue the test when a first error has been detected. This error must not perturb the operation of the second signal generator 10 by propagating through the second shift register R2. To this end, an error correction device 17 may be provided, which, when ah error has been detected in a bit of the output sequence, corrects the value of this bit before the bit enters the second shift register R2. FIG. 3C illustrates this configuration. The error correction device 17 is realized by a fourth exclusive-OR gate, one input of which is connected to the output of the information means 14 indicating the presence of an error, and the other input receives the sequence of output bits, while its output is connected to the input of the second shift register R2. This fourth exclusive-OR gate inverts the value of the bit of the sequence of output bits reaching its input when an error is detected.

In FIG. 3C, one of the inputs of the fourth exclusive-OR gate 17 is connected to the output of the third exclusive-OR gate 13, because the validation device 15 has not been shown. If this device were present, as in FIG. 3D, the input of the fourth exclusive-OR gate 17 would be connected to the output of the AND gate 15-2.

Notably for estimating the quality of the connection to be tested, it may be necessary to count the number of errors affecting this connection. For example, one may want to know the error rate of the connection during a test of a given duration. It is sufficient to count the number of errors appearing during performance of the test. Counting means 16 are shown in FIG. 3D. They are connected to the information means 14 for indicating the presence of an error. When one wants to know the number of errors during a test, the counting means 16 may be realized by a conventional counter which is reset to zero at the end of the test.

It may be envisaged that these counting means 16 supply a signal when a predetermined number of errors is reached. A programmable counter 16-1 which triggers an SR flipflop 16-2 may be used when the predetermined number of errors is reached. The SR flipflop 16-2, reset to zero before the counting starts supplies the expected signal. The programmable counter 16-1 may count until, for example, one, two, four or eight, dependent on the number of bits.

To improve the reliability of the test device, it is preferable that the sequence of output bits is perfectly synchronized, i.e. in phase with the clock signal h. A D-flipflop 18 may be used as a synchronizing means. It receives the clock signal h. Its input D receives the sequence of output bits, its output Q supplies the same sequence but synchronized with the clock signal h. Such a D-flipflop 18 triggers at the leading edges of the clock.

For safety's sake, the possibility of inverting the direction of the clock pulses may be provided in order that the synchronization of the sequence of output bits can be effected when the bits of the output sequence have a value which has been established and not a value during a transition. The means for inverting the clock signals are denoted by reference numeral 19. In all the cases, the same clock signal controls the second shift register R2 and the D-flipflop 18. As for the two signal generators, which are controlled by the same frequency, their phase difference is less important.

Finally, a self-test device 20 of the error detection device 6 may be provided. By activating this device, the satisfactory operation of the error detection device 6 can then be ensured. During the performance of this self-test, a test sequence is generated which has one or more calibrated errors that are perfectly known. This erroneous test sequence is substituted for the sequence of output bits at the level of the second shift register R2, the information means 14 indicating the presence of an error and the error correction device 17. The signal supplied by the counting means 16 must be coherent with the number of introduced errors. When the self-test device 20 is not activated, it is transparent to the sequence of output bits.

1. A device for testing the conformity of an electronic connection (1), the device comprising a first signal generator (3) supplying a sequence of input bits to a first extremity (E) of the connection (1), and an error detection device (6) receiving a sequence of output bits from a second extremity (S) of the connection (1), in response to the sequence of input bits, characterized in that the error detection device (6) comprises:
a second signal generator (10), similar to the first generator (3), this second signal generator (10) being intended to recreate the sequence of input bits and being suitable for predicting the value of the next bit when the second extremity (S) supplies a bit of the output sequence, and
information means (14) indicating the presence of an error with means (13) for comparing the value of the predicted bit with the effective value of the next bit of the sequence of output bits.

2. A test device as claimed in claim 1, characterized in that a clock signal at the same frequency controls the first signal generator (3) and the second signal generator (10).

3. A test device as claimed in claim 1 or 2, characterized in that the first signal generator (3) comprises a first shift register (R1) loaded with an initial combination of the bits, associated with a first exclusive-OR gate (7) connected, at the input, to the last stage and to the stage before the last stage of the first shift register (R1), and, at the output, to the first stage of the first shift register (R1).

4. A test device as claimed in claim 3, characterized in that the combination of initial bits is supplied by possibly programmable initialization means (8).

5. A test device as claimed in any one of claims 1 to 4, characterized in that the second signal generator (10) comprises a second shift register (R2), associated with a second exclusive-OR gate (11) connected, at the input, to the last stage and to the stage before the last stage of the second shift register (R2), and whose output supplies the bit with the predicted value.

6. A test device as claimed in claim 5, where appendant to claim 3, characterized in that the output of the second exclusive-OR gate (11) is connected to the first stage of the second shift register (R2), the second shift register (R2) being loaded with the same initial combination of bits as the first shift register (R1).

7. A test device as claimed in claim 6, characterized in that the start of operation of the second shift register (R2) is synchronized with the start of the sequence of output bits.

8. A test device as claimed in claim 5, characterized in that the first stage of the second shift register (R2) receives the sequence of output bits.

9. A test device as claimed in any one of claims 1 to 8, characterized in that the comparison means (13) comprise a third exclusive-OR gate (13), one input of which is connected to the second signal generator (10) and the other input receives the sequence of output bits.

10. A test device as claimed in claim 9, characterized in that the information means (14) indicating the presence of an error also comprise a device (15) for validating errors, intended to mask errors which might be detected when the second signal generator (10) is not in an operational state.

11. A test device as claimed in claim 10, characterized in that the validation device (15) comprises an AND gate (15-2), one input of which is connected to the output of the comparison means (13), and the other input is connected to a delay device (15-1) which brings about a delay (Δ′) which is compatible with the operational state of the second signal generator (10).

12. A test device as claimed in any one of claims 8 to 11, characterized in that it comprises an error correction device (17) intended to correct an error of the sequence of output bits before its input into the second stage of the second shift register (R2).

13. A test device as claimed in claim 12, characterized in that the correction device (17) comprises a fourth exclusive-OR gate, one input of which receives the sequence of output bits and the other input is connected to the output of the information means (14) indicating the presence of an error, and whose output is connected to the first stage of the second shift register (R2).

14. A test device as claimed in any one of claims 1 to 13, characterized in that it comprises means (16) for counting detected errors, arranged at the output of the information means (14) indicating the presence of an error.

15. A test device as claimed in claim 14, characterized in that the counting means (16) supply a signal when a predetermined number of errors has occurred.

16. A test device as claimed in claim 15, characterized in that the counting means (16) comprise a programmable counter (16-1), whose input receives the information indicating the presence of an error and whose output is connected to the input of a D-flip-flop (16-2) which supplies the signal.

17. A test device as claimed in any one of claims 1 to 16, characterized in that it comprises a self-test device (20).

18. A test device as claimed in any one of claims 2 to 17, characterized in that it comprises means (18) for synchronizing the sequence of output bits with the clock signal.

19. A test device as claimed in claim 18, characterized in that the means (18) for synchronizing the sequence of output bits with the clock signal are realized by a D-flip-flop.

20. A test device as claimed in claim 18 or 19, characterized in that it comprises means (19) for inverting the clock signal so as to facilitate the synchronization.
